(19) United States
(12) Patent Application Publication
(10) Pub. No.: US 2022/0004071 A1
(43) Pub. Date: Jan. 6, 2022

(54) DISPLAY DEVICE

(71) Applicant: Japan Display Inc., Tokyo (JP)

(72) Inventors: Masashi TSUBUKU, Tokyo (JP); Makoto UCHIDA, Tokyo (JP); Takashi NAKAMURA, Tokyo (JP)

(73) Assignee: Japan Display Inc., Tokyo (JP)

(21) Appl. No.: 17/448,419

(22) Filed: Sep. 22, 2021

Related U.S. Application Data
(63) Continuation of application No. PCT/JP2020/011181, filed on Mar. 13, 2020.

(30) Foreign Application Priority Data
Mar. 29, 2019 (JP) 2019-068402

(51) Int. Cl. G02F 1/1362; G02F 1/1368

(52) U.S. Cl. CPC G02F 1/136286; G02F 2202/104; G02F 1/1368

(57) ABSTRACT

A display device includes: a display portion, a first transistor arranged in the display portion and including a first semiconductor layer, a second transistor arranged adjacent to the first transistor in the display portion and including a second semiconductor layer arranged in a different layer from the first semiconductor layer, a first signal line connected to the first transistor, a second signal lime connected to the second transistor, a gate line overlapping the first transistor and the second transistor, and a display element arranged on the first transistor and the second transistor.

### CROSS REFERENCE TO RELATED APPLICATIONS

This application is a U.S. continuation application filed under 35 U.S.C. § 111(a), of International Application No. PCT/JP2020/011181, filed on Mar. 13, 2020, which claims priority to Japanese Patent Application No. 2019-068402, filed on Mar. 29, 2019, the disclosures of which are incorporated herein by reference.

### FIELD

An embodiment of the present invention relates to a display device.

### BACKGROUND

A liquid crystal display device using the electro-optic effect of a liquid crystal, and an organic electroluminescent display device using an organic electro luminescence (organic EL) element have been developed as a display device used in electric appliances and electronic equipment. In recent years, a display device having a large area, a high resolution, and a high frame rate, and the like have been increasingly demanded. Therefore, efforts have been actively made to satisfy these requirements. In particular, it is expected that a high-definition display device will be needed in the future as applications of augmented reality (AR) or virtual reality (VR).

Conventionally, transistors using silicon as a semiconductor layer have been used in these display devices. Recently, transistors using an oxide semiconductor have been developed instead of silicon. The transistors using an oxide semiconductor are expected to be able to realize high mobility. Furthermore, an oxide semiconductor can be formed with a large area and has an advantage of excellent high-pressure resistance compared to amorphous silicon. Japanese laid-open patent publication No. 2006-165528 discloses a display device using an oxide semiconductor.

### SUMMARY

A display device according to an embodiment of the present invention includes a display portion, a first transistor arranged in the display portion and including a first semiconductor layer, a second transistor arranged adjacent to the first transistor in the display portion and including a second semiconductor layer arranged in a different layer from the first semiconductor layer, a first signal line connected to the first transistor, a second signal line connected to the second transistor, a gate line overlapping the first transistor and the second transistor, and a display element arranged on the first transistor and the second transistor.

### BRIEF DESCRIPTION OF THE DRAWINGS

FIG. 1 is a plan view of a display device according to an embodiment of the present invention;

FIG. 2 is a circuit diagram of a pixel circuit of a display device according to an embodiment of the present invention;

FIG. 3 is an enlarged top view of a part of a display portion of a display device according to an embodiment of the present invention;

FIG. 4 is an enlarged cross-sectional view of a part of a display portion of a display device according to an embodiment of the present invention;

FIG. 5 is a cross-sectional view of a method of manufacturing a transistor according to an embodiment of the present invention;

FIG. 6 is a cross-sectional view of a method for manufacturing a transistor according to an embodiment of the present invention;

FIG. 7 is a cross-sectional view of a method for manufacturing a transistor according to an embodiment of the present invention;

FIG. 8 is a cross-sectional view of a method for manufacturing a transistor according to an embodiment of the present invention;

FIG. 9 is a cross-sectional view of a method for manufacturing a transistor according to an embodiment of the present invention;

FIG. 10 is a cross-sectional view of a method for manufacturing a transistor according to an embodiment of the present invention;

FIG. 11 is an enlarged cross-sectional view of a part of a display portion of a display device according to an embodiment of the present invention;

FIG. 12 is an enlarged top view of a part of a display portion of a display device according to an embodiment of the present invention;

FIG. 13 is a cross-sectional view of a transistor according to the present embodiment;

FIG. 14 is a result of reliability evaluation of a transistor according to an example; and

FIG. 15 is a result of reliability evaluation of a transistor according to an example.

### DESCRIPTION OF EMBODIMENTS

In manufacturing a high-definition display device, when forming semiconductor layers of a display portion on the same surface, processing limitations of the manufacturing device occur in addition to limitations on the area of each layer that can be arranged. Therefore, a problem arises in realizing a display device with higher definition.

In view of the above problems, an object of an embodiment of the present invention is to provide a high-definition display device.

Embodiments of the present invention will be described below with reference to the drawings and the like. However, the present invention can be implemented in many different modes, and should not be construed as being limited to the description of the following embodiments. For the sake of clarity of explanation, although the drawings may be schematically represented with respect to widths, thicknesses, shapes, and the like of the respective portions in comparison with actual embodiments, they are only examples and do not limit the interpretation of the present invention. In this specification and each of the drawings, the same reference numerals (or reference numerals denoted by A, B, and the like) are given to the same elements as those described above with reference to the preceding drawings, and a detailed description thereof may be omitted as appropriate. In addition, the letters “first” and “second” attached to each element are convenient labels used to distinguish each element and have no further meaning unless otherwise stated. In this specification, the case where one member or area is “above (or below)” other member or region includes not only the case where it is directly above (or below) another member or region, but also the case where it is above (or below) another member or region, i.e., the case where another component is included in between above (or below) another member or region. In the following description, unless otherwise specified, in the cross-sectional view, the side on which the second substrate is arranged with respect to the first substrate is referred to as “upper”, and the opposite is referred to as “lower”.

In this specification, “A and B are connected” means not only that A and B are directly connected, but A and B are electrically connected. In this case, the term “A and B are electrically connected” means that an electric signal can be exchanged between A and B when an object having some electric action exists between A and B.

In addition, in the case of components which can be recognized by a person ordinarily skilled in the art to which the present invention belongs, no special explanation shall be provided.

### First Embodiment

### (1-1. Configuration of Display Device)

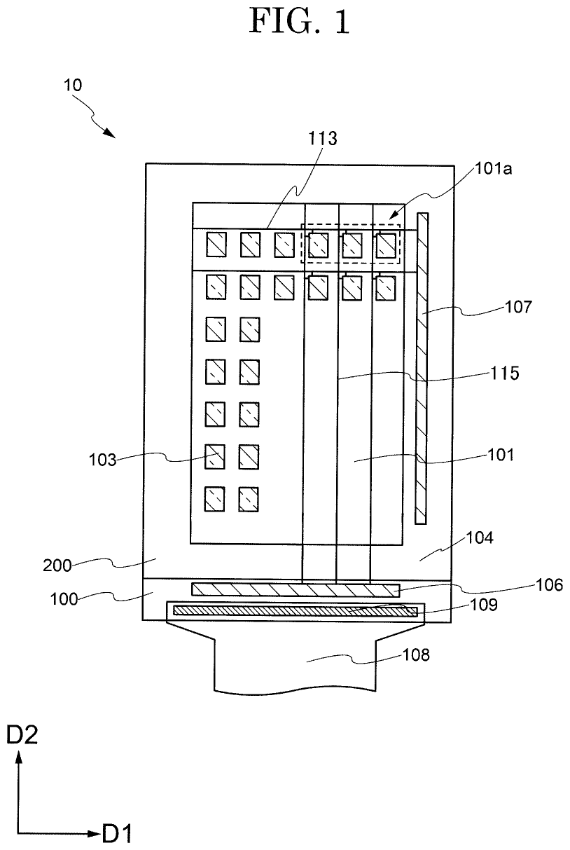

FIG. 1 shows a top view of a display device 10. In FIG. 1, the display device 10 includes a substrate 100, a substrate 200, a display portion 101 having a plurality of pixels 103, a drive circuit 106 having a function as a source driver, a periphery portion 104 having a drive circuit 107 having a function as a gate driver, a flexible printed circuit board 108, and a terminal portion 109.

In FIG. 1, the pixel 103 is provided in a matrix, and includes display elements (liquid crystal elements 170 to be described later). The periphery portion 104 is arranged on the outside of the display portion 101, and is provided so as to surround the display portion 101. The pixel 103, the drive circuit 106, the drive circuit 107, and the flexible printed circuit board 108 are electrically connected, respectively. Information (signal) from an external device is input to the drive circuit 106 and the drive circuit 107 via the flexible printed circuit board 108, and the terminal portion 109. A gate line 113 is connected to the drive circuit 106. The gate line 113 extends in a first direction D1 and is arranged side by side in a second direction D2 intersecting the first direction D1. A signal line 115 is connected to the drive circuit 107. The signal line 115 extends in the second direction and is arranged side by side in the first direction.

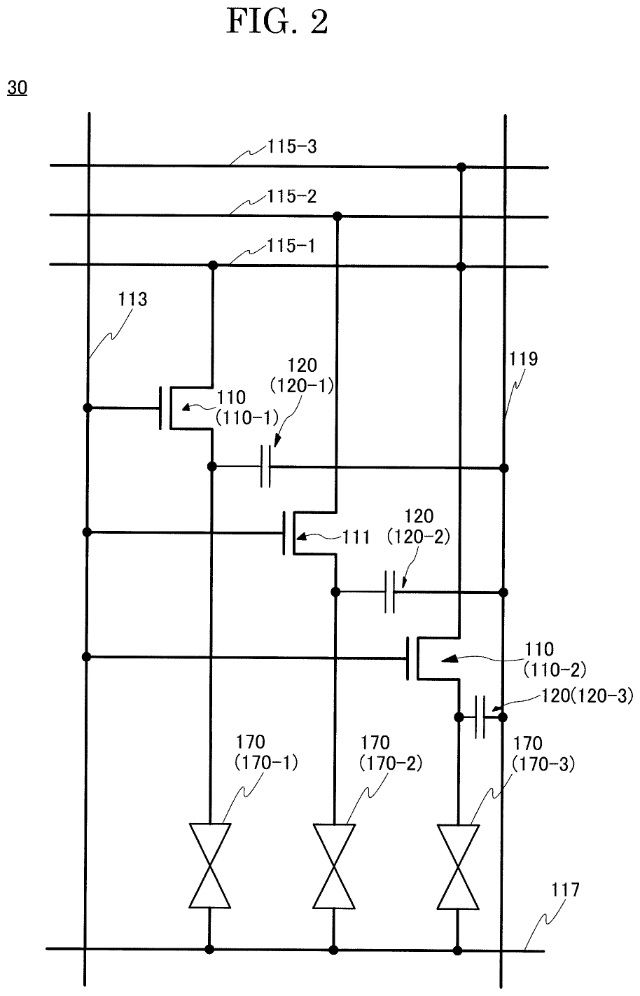

FIG. 2 shows a circuit diagram of a pixel circuit 30 in the display portion 101 of the display device 10. The circuit configuration of the pixel circuit 30 described below is an example, and is not limited thereto.

The pixel circuit 30 includes at least transistors 110 (transistor 110-1 and transistor 110-2), a transistor 111, and a capacitance element 120 and the liquid crystal elements 170 connected to each of the transistors 110 and the transistor 111. The transistors 110 and 111 can be collectively referred to as a semiconductor device. When it is not necessary to distinguish the transistors 110-1 and 110-2, they will be described as the transistor 110. Similarly, when it is not necessary to distinguish a signal line 115-1, a signal line 115-2, and a signal line 115-3, they may be described as the signal line 115.

The transistor 110 (transistor 110-1) is connected to the liquid crystal element 170 (liquid crystal element 170-1) and controls the orientation of a liquid crystal included in the liquid crystal element 170-1. In the transistor 110-1, the drain current is controlled by a voltage between the gate and source. In the transistor 110-1, the gate is connected to the gate line 113, one of the source or drain is connected to the signal line 115-1, and the other of the source or drain is connected to a first electrode of the liquid crystal element 170. A second electrode of the liquid crystal element 170-1 is connected to a common potential line 117. One electrode of the capacitance element 120 (capacitance element 120-1) is connected to the other of the source or drain of the transistor 110-1. The other electrode of the capacitance element 120 is connected to a capacitance wiring 119. The transistor 110-1 is a component of the pixel 103 (pixel 103-1).

The transistor 111 is connected to the liquid crystal element 170 (liquid crystal element 170-2) and controls the orientation of the liquid crystal contained in the liquid crystal element 170-2. The drain current of the transistor 111 is controlled by a voltage between the gate and source. The transistor 111 has a gate connected to the gate line 113, one of the source or drain is connected to the signal line 115-2, and the other of the source or drain is connected to the first electrode of the liquid crystal element 170-2. A second electrode of the liquid crystal element 170-2 is connected to the common voltage line 117. One electrode of the capacitance element 120 (capacitance element 120-2) is connected to the other of the source or drain of the transistor 111. The other electrode of the capacitance element 120-2 is connected to the capacitance wiring 119. The transistor 111 is a component of the pixel 103 (pixel 103-2).

The transistor 110-2 is connected to a liquid crystal element 170-3 and controls the orientation of the liquid crystal contained in the liquid crystal element 170-3. The drain current of the transistor 110-2 is controlled by a voltage between gate and source. The transistor 110-2 has a gate connected to the gate line 113, one of the source or drain is connected to the signal line 115-3, and the other of the source or drain is connected to the first electrode of the liquid crystal element 170-2. A second electrode of the liquid crystal element 170-3 is connected to the common voltage line 117. One electrode of a capacitance element 120-3 is connected to the other of the source or drain of the transistor 110-2. The other electrode of the capacitance element 120-3 is connected to the capacitance wiring 119. The transistor 110-2 is a component of the pixel 103 (pixel 103-3).

In this example, although the transistor 110-1, the transistor 111, and the transistor 110-2 are connected to the gate line 113, the transistor 110-1, the transistor 111, and the transistor 110-2 may be connected to different gate lines, as described below.

Based on the above-described configuration, a video signal transmitted from the drive circuit 106 and a scanning signal (gate signal) transmitted from the drive circuit 107 are input to the respective pixels 103. As a result, a still image and a moving image are displayed on the display portion 101.

### (1-2. Pixel Configuration)

Next, each configuration of the pixel 103-1, the pixel 103-2, and the pixel 103-3 provided on the display portion 101 of the display device 10 will be described with reference to the drawings.

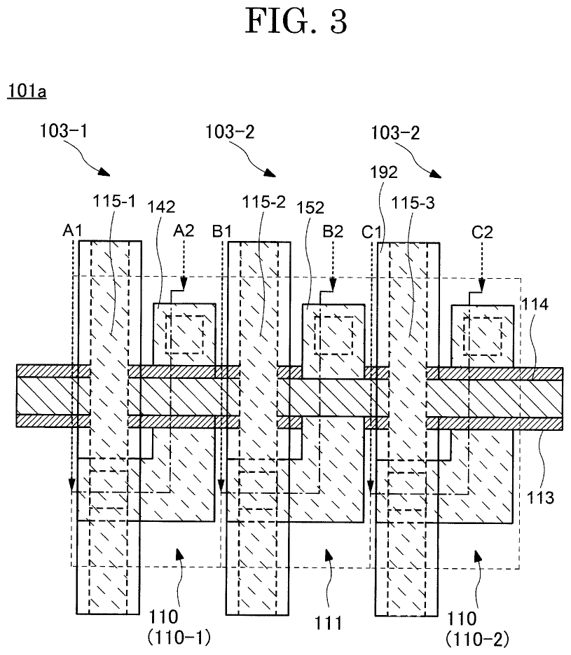

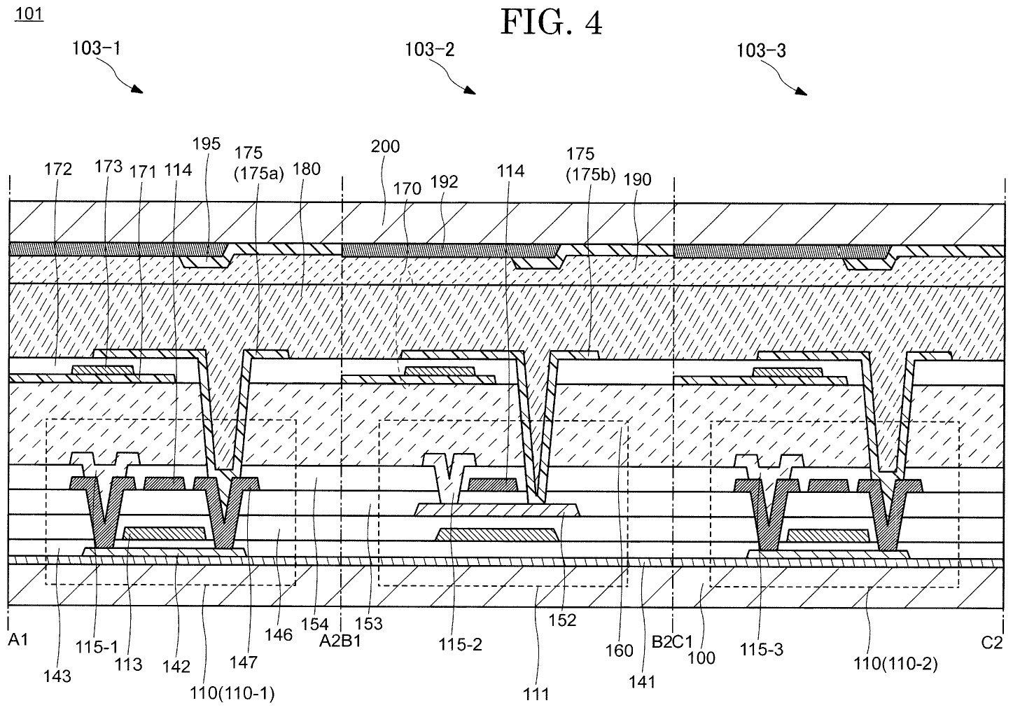

FIG. 3 is a top view of an area 101a of the display portion 101 in the display device 10 shown in FIG. 1. FIG. 4 is a cross-sectional view between A1-A2 of the pixel 103-1, between B1-B2 of the pixel 103-2, and between C1-C2 of the pixel 103-3. As shown in FIGS. 3 and 4, the display portion 101 includes the substrate 100, the transistors 110 (transistor 110-1 and transistor 110-2), the transistor 111, the liquid crystal element 170, and the substrate 200. Each configuration will be described in detail below.

### (1-2-1. Configuration of Transistor)

As shown in FIGS. 3 and 4, the transistor 110-1 of the transistor 110 has a semiconductor layer 142, an insulating layer 143, the gate line 113, an insulating layer 146, an insulating layer 153, an insulating layer 154, source/drain electrodes 147, and the signal line 115-1. The transistor 110-2 has the same configuration as the transistor 110-1, and the explanation of the transistor 110-2 will be omitted.

The transistor 111 is arranged adjacent to the transistor 110. The transistor 111 has the insulating layer 143, the gate line 113, the insulating layer 146, an oxide semiconductor layer 152, the insulating layer 153, a gate line 114, the insulating layer 154, and the signal line 115-2.

As shown in FIG. 3, the semiconductor layer 142 and the oxide semiconductor layer 152 are provided apart from each other in a plan view. The gate line 113 and the gate line 114 are arranged to overlap the semiconductor layer 142 and the oxide semiconductor layer 152.

The semiconductor layer 142 (also referred to as a first semiconductor layer) is provided on the insulating layer 141. The semiconductor layer 142 contains a silicon material. Specifically, the semiconductor layer 142 contains polysilicon. The semiconductor layer 142 is not limited to polysilicon, and amorphous silicon, microcrystalline silicon, or single crystal silicon may be used for the semiconductor layer 142.

The insulating layer 143 functions as a gate insulating layer. A high dielectric constant material is used for the insulating layer 143. Silicon Nitride (SiNₓ), silicon oxide (SiOₓ), silicon oxynitride (SiOₓN_{y}), aluminum nitride (AlNₓ), aluminum oxide (AlOₓ), or aluminum oxynitride (AlOₓN_{y}) (x, y is an optional integer) or the like is used as the insulating layer 143. The insulating layer 143 may have a single-layer structure or a stacked-layer structure of the above materials. The insulating layer 143 in contact with the oxide semiconductor layer 152 is preferably an insulating layer containing oxygen such as a silicon oxide film.

The gate line 113 (also referred to as a first gate line) is provided on the insulating layer 143. In the transistor 110, the gate line 113 overlaps the semiconductor layer 142. Aluminum (Al), titanium (Ti), chromium (Cr), cobalt (Co), nickel (Ni), zinc (Zn), molybdenum (Mo), copper (Cu), indium (In), tin (Sn), hafnium (Hf), tantalum (Ta), tungsten (W), platinum (Pt), bismuth (Bi) or the like is used for the gate line 113 as the conductive material. An alloy of these metals may be used for the gate line 113. A conductive oxide such as ITO (indium tin oxide), IGO (indium gallium oxide), IZO (indium zinc oxide), or GZO (zinc oxide to which gallium is added as a dopant) may be used for the gate line 113. These films may be stacked.

The insulating layer 146 is provided on the insulating layer 143. The insulating layer 146 is provided between the gate line 113 and the oxide semiconductor layer 152 and has a function as a gate insulating layer. A material similar to that of the insulating layer 143 may be used for the insulating layer 146.

The oxide semiconductor layer 152 (also referred to as a second semiconductor layer) is provided on the insulating layer 146. Therefore, it can be said that the transistor 111 includes a semiconductor layer provided on a layer different from that of the transistor 110. The oxide semiconductor layer 152 is arranged overlapping the gate line 113. The oxide semiconductor layer 152 contains an oxide semiconductor material that is different from that of the semiconductor layer 142. Specifically, the oxide semiconductor layer 152 can contain a Group 13 element such as indium or gallium. The oxide semiconductor layer 152 may contain a plurality of different Group 13 elements. The oxide semiconductor layer 152 may further contain a Group 12 element. For example, a compound (IGZO) containing indium, gallium, and zinc is used for the oxide semiconductor layer 152.

The oxide semiconductor layer 152 may contain other elements. The oxide semiconductor layer 152 may contain tin as a Group 14 element, and titanium or zirconium as a Group 4 element, and the like.

Materials such as InOₓ, ZnOₓ, SnOₓ, In—Ga—O, In—Zn—O, In—Al—O, In—Sn—O, In—Hf—O, In—Zr—O, In—W—O, In—Y—O, In—Ga—Zn—O, In—Al—Zn—O, In—Sn—Zn—O, In—Hf—Zn—O, In—Ga—Sn—O, In—Al—Sn—O, In—Hf—Sn—O, In—Ga—Al—Zn—O, In—Ga—Hf—Zn—O, In—Sn—Ga—Zn—O may be used as other embodiments of the oxide semiconductor layer 152. The crystallinity of the oxide semiconductor layer 152 is not limited, and may be single crystal, polycrystalline, microcrystalline, or amorphous.

The insulating layer 153 is provided on the insulating layer 146. The insulating layer 153 is provided between the gate line 114 and the oxide semiconductor layer 152 and also functions as a gate insulating layer. A material similar to that of the insulating layer 143 may be used for the insulating layer 153.

The gate line 114 and the source/drain electrodes 147 are provided on the semiconductor layer 142 and the insulating layer 153. The gate line 114 overlaps the gate line 113, the semiconductor layer 142, and the oxide semiconductor layer 152. The source/drain electrodes 147 are connected in part to the semiconductor layer 142. A low resistance metal material is used for the gate line 114 and the source/drain electrodes 147. Specifically, aluminum (Al), titanium (Ti), chromium (Cr), cobalt (Co), nickel (Ni), zinc (Zn), molybdenum (Mo), copper (Cu), indium (In), tin (Sn), hafnium (Hf), tantalum (Ta), tungsten (W), platinum (Pt), and bismuth (Bi), or the like is used for the gate line 114 and the source/drain electrodes 147. An alloy of these metals may be used for the gate line 114 and the source/drain electrodes 147. These films may be stacked as the gate line 114 and the source/drain electrodes 147.

The insulating layer 154 is provided on the insulating layer 153. A material similar to that of the insulating layer 143 may be used, or an organic material may be used for the insulating layer 154. Specifically, an organic resin such as an acrylic resin, an epoxy resin, or a polyimide resin may be used for the insulating layer 154.

The signal line 115-1, the signal line 115-2 and the signal line 115-3 are provided on the insulating layer 154. That is, it can be said that the signal line 115-1, the signal line 115-2, and the signal line 115-3 are provided on the same layer. As a result, the degree of freedom in designing the display portion can be increased. The signal line 115-1 and the signal line 115-3 are connected to the source/drain electrodes 147. The signal line 115-2 is connected to the oxide semiconductor layer 152. A material similar to that of the source/drain electrodes 147 may be used for the signal line 115-1 and the signal line 115-2.

With the above configuration, in the transistor 110, the gate line 113 and the gate line 114 are arranged to overlap on the upper side of the semiconductor layer 142. In other words, the gate line 113 is arranged between the semiconductor layer 142 and the gate line 114. In this case, in the transistor 110, the gate line 114 has a configuration in which a voltage is not directly applied to the semiconductor layer 142. In this embodiment, the transistor 110 has a top gate and a top contact structure.

On the other hand, in the transistor 111, the oxide semiconductor layer 152 is provided between the gate line 113 and the gate line 114. The gate line 113 may apply a gate voltage from the lower side of the oxide semiconductor layer 152, and the gate line 114 may apply a voltage from the upper side of the oxide semiconductor layer 152. The same potential can be applied to the gate line 113 and the gate line 114. In the present embodiment, the transistor 111 has a dual gate and a top contact structure.

In the present embodiment, in the display portion 101, the semiconductor layers used in the transistors included in adjacent pixels in the display portion 101 are arranged at different positions. Thus, the design and fabrication constraints of the semiconductor layer in manufacturing a high-definition display device are determined by the arrangement of the semiconductor layers of the transistors included in two adjacent pixels (in the present embodiment, corresponding to the transistor 110-2 with respect to the transistor 110-1). Therefore, it is easy to process and form the semiconductor layers of the transistors included in the respective pixels in the display portion. Therefore, it becomes easier to manufacture a high-definition display device.

Polysilicon or single crystal silicon has a feature of high field-effect mobility when used for the semiconductor layer 142 of the transistor 110. Therefore, in the drive circuit 106 and the drive circuit 107 of the periphery portion 104 provided on the outside of the display portion 101, it is desirable to arrange a transistor (also referred to as a third transistor) having a semiconductor layer in the same layer as the semiconductor layer 142 of the transistor 110. The third transistor may have a high field-effect mobility. Therefore, the drive circuit including the third transistor can increase the drive speed of the display device, and is compatible with a high-speed display.

### (1-2-2. Other Configurations of Display Device)

Next, each of the other configurations of the display portion 101 will be described below.

A glass substrate or an organic resin substrate is used for the substrate 100. For example, polyimide is used for the organic resin substrate. The organic resin substrate is not limited to polyimide, and polyethylene terephthalate, polyethylene naphthalate, triacetyl cellulose, cyclic olefin copolymer, and cycloolefin polymer may be used for the organic resin substrate. The thicknesses of the substrate 100 and the substrate 200 can be set as appropriate. For example, in a case of an organic resin substrate, the thickness can be several micrometers to several tens of micrometers. In this case, it is possible to realize a flexible sheet display.

The insulating layer 141 has a function as a base film. Silicon oxide, silicon oxide nitride, silicon nitride, or the like is used for the insulating layer 141. The insulating layer 141 may be a single layer or have a stacked layer structure. By using the above materials, impurities, typically alkali metal, water, hydrogen, or the like, can be prevented from diffusing from the substrate 100 to the oxide semiconductor layer 152.

A planarization layer 160 is provided on the insulating layer 154. An organic material such as a polyimide resin, a polyamide resin, an acrylic resin, or an epoxy resin is used for the planarization layer 160. These materials have the advantages that it is possible to form a film using a solution coating method and have a high flattening effect.

A common electrode 171 is provided on the planarization layer 160. A transparent conductive material is used for the common electrode 171. Although indium tin oxide (ITO) is used in this example, zinc oxide (ZnO), or indium zinc oxide (IZO), or the like may also be used. In FIG. 4, the common electrode 171 is arranged in each pixel, but may be provided across each pixel.

A conductive layer 173 may be provided on the common electrode 171. A material having a low resistance similar to the gate line 113 and the gate electrode layer 145b is used for the conductive layer 173. Specifically, a stacked film of titanium, aluminum, and titanium is used for the conductive layer 173. The conductive layer 173 may not necessarily be provided.

The insulating layer 172 is provided on the common electrode 171 and the planarization layer 160. A silicon oxide film or a silicon nitride film is used for the insulating layer 172.

A pixel electrode 175a and a pixel electrode 175b are provided on the insulating layer 172. Similar to the common electrode 171, a transparent conductive material is used for the pixel electrodes 175a and 175b. In this example, indium tin oxide (ITO) is used. The pixel electrode 175a is connected to the source/drain electrodes 147 via an opening. The pixel electrode 175b is connected to the oxide semiconductor layer 152 via the opening. Therefore, the pixel electrode 175b can function as the source/drain electrodes. Although not shown, the pixel electrode 175b may be connected to the source/drain electrodes via another electrode. Although not shown, the pixel electrodes 175a and 175b are separated for each pixel in a plan view and are provided in a comb-tooth shape.

A light-shielding layer 192 is provided on the substrate 200 side. The light-shielding layer 192 has a function of shielding light. For example, in addition to a resin in which a pigment is dispersed and a resin containing a dye, an inorganic film such as a black chromium film, carbon black, a composite oxide containing a solid solution of a plurality of inorganic oxides, and the like can be used.

A color filter layer 195 is provided in the opening of the light-shielding layer 192. The color filter layer 195 has a function of transmitting light of a specific wavelength band with respect to light transmitted and emitted from the liquid crystal element 170. For example, light in a red, green, or blue wavelength band can be transmitted.

A planarization layer 190 is provided on the color filter layer 195 and the light-shielding layer 192. A material similar to the planarization layer 160 is used for the planarization layer 190.

A liquid crystal layer 180 is provided between the pixel electrode 175 (the pixel electrode 175a or the pixel electrode 175b) and the planarization layer 190. The liquid crystal element 170 of the present embodiment, which includes the pixel electrode 175 (the pixel electrode 175a or the pixel electrode 175b), the common electrode 171, and the liquid crystal layer 180, is an FFS (Fringe Field Switching) liquid crystal element. The liquid crystal element is not limited to the FFS liquid crystal element and may be a TN (Twisted Nematic) type liquid crystal element, or may be a VA (Vertical Alignment) type liquid crystal element.

A glass substrate, a quartz substrate, or a flexible substrate (polyimide, polyethylene terephthalate, polyethylene naphthalate, triacetyl cellulose, a cyclic olefin copolymer, a cycloolefin polymer, or other flexible resin substrate) can be used for the substrate 200.

### (1-3. Method for Manufacturing Display Device)

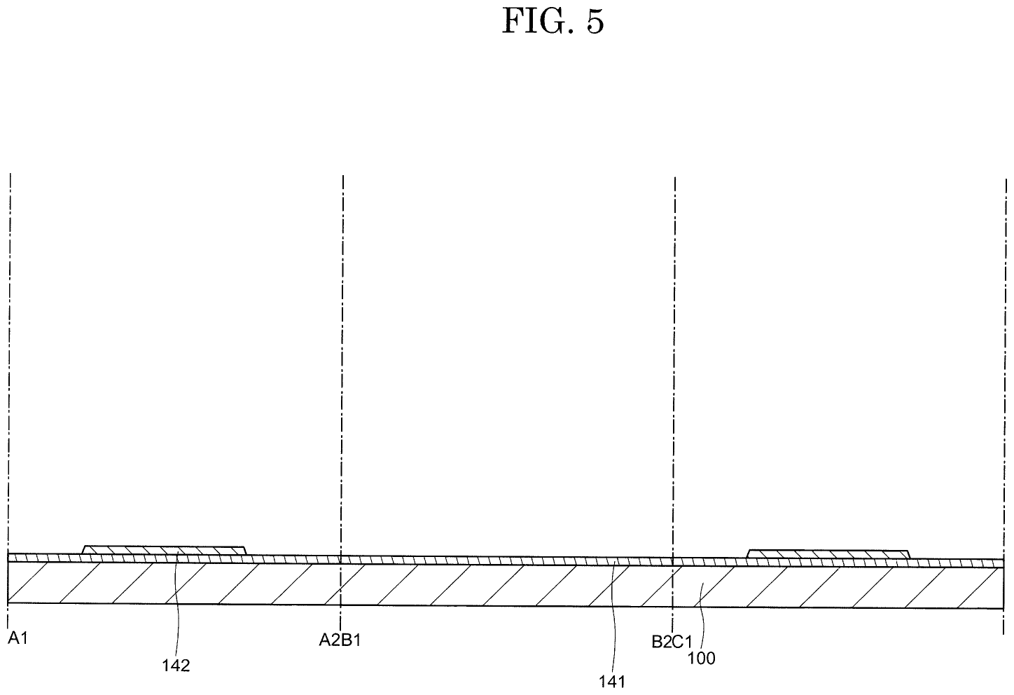

Next, a method of manufacturing the display device 10 will be described with reference to FIGS. 5 to 10 while focusing on the transistor 110 and the transistor 111.

First, as shown in FIG. 5, the semiconductor layer 142 is formed on the insulating layer 141 provided on the substrate 100. The semiconductor layer 142 is formed by a CVD method, a sputtering method, or a vapor deposition method, or the like. In this example, a silicon film formed by a CVD method is used for the semiconductor layer 142. The semiconductor layer 142 is polycrystallized by a heat treatment or laser irradiation. As a result, the semiconductor becomes polysilicon. For example, the temperature used in the heat treatment is 500° C. or higher. The semiconductor layer 142 is processed to have a desired shape using a photolithography method and a dry etching method or a wet etching method.

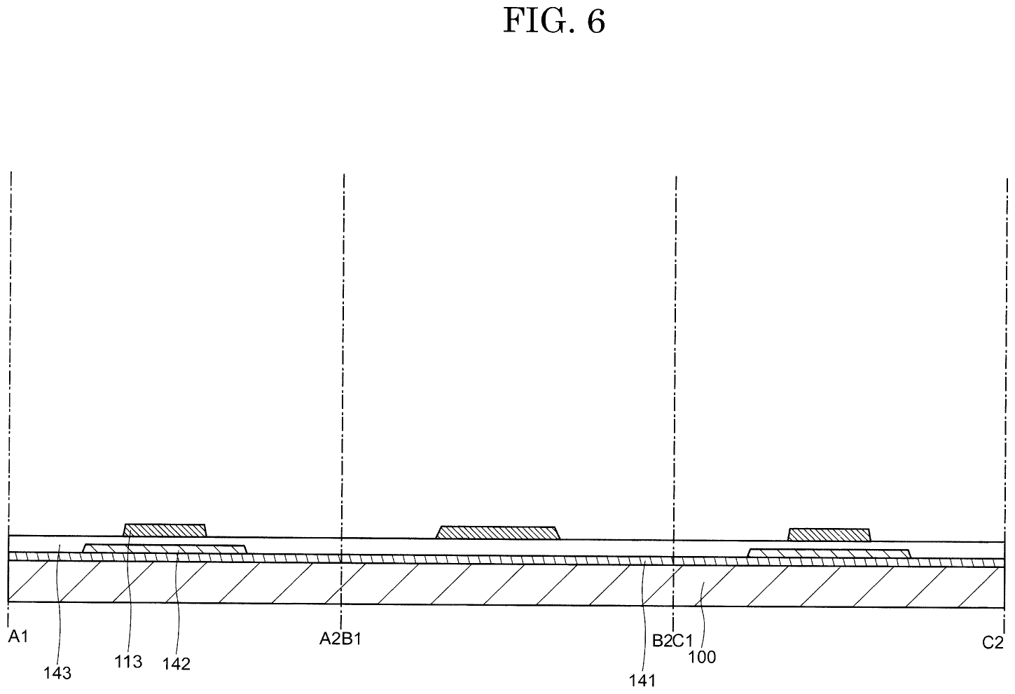

Next, as shown in FIG. 6, the insulating layer 143 and the gate line 113 are formed.

The insulating layer 143 is formed by a sputtering method, a thermal CVD method, or a plasma CVD method using the materials described above. In this example, a silicon oxide film formed by a CVD method with a thickness of 30 nm or more and 300 nm or less, is used for the insulating layer 143.

The gate line 113 is formed by a conductive film formed on the insulating layer 143 and is processed to a desired shape by a photolithographic method and a dry etching method or a wet etching method. The conductive film is formed to have a single-layer structure or a stacked-layer structure using any of the above materials by a sputtering method. The film thickness of the gate line 113 is preferably 100 nm or more and 1000 nm or less. In this example, an alloy film of molybdenum and tungsten is used for the gate line 113.

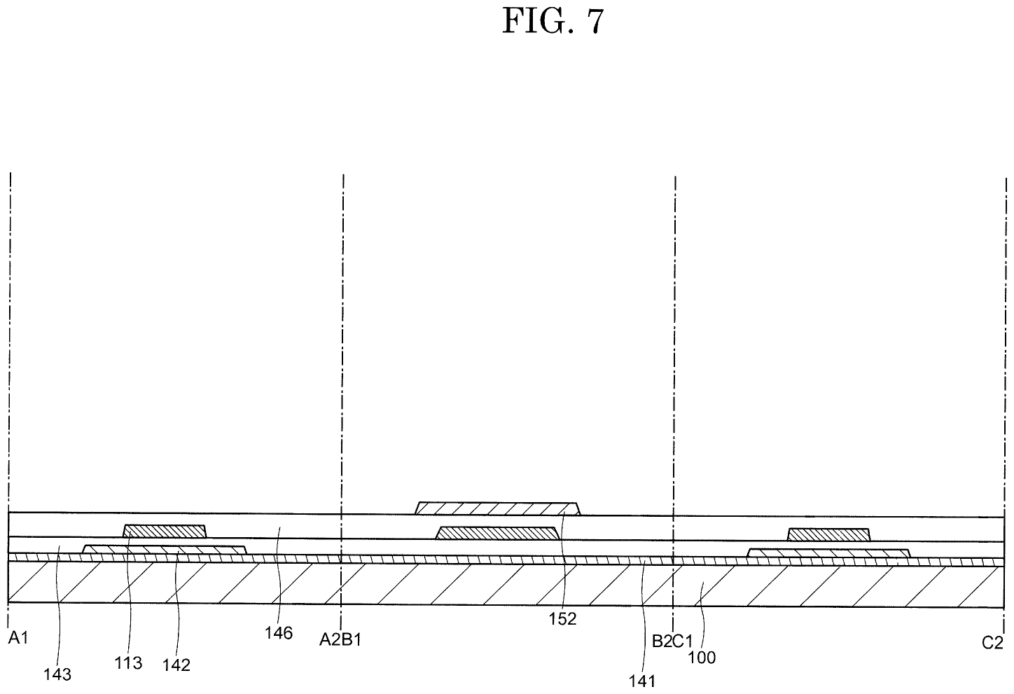

Next, as shown in FIG. 7, the insulating layer 146 and the oxide semiconductor layer 152 are formed. A silicon oxide film, a silicon nitride film, or a stacked film thereof is used for the insulating layer 146. The thickness of the insulating layer 146 is 50 nm or more and 600 nm or less.

The oxide semiconductor layer 152 is formed on the insulating layer 143 using a sputtering method, and is processed to have a desired shape by a photolithography method and a dry etching method. The thickness of the oxide semiconductor layer 152 is 30 nm or more and 200 nm or less.

When forming the oxide semiconductor film corresponding to the oxide semiconductor layer 152 by a sputtering method, the power supply to be applied to the oxide semiconductor target may be a direct current (DC) or an alternating current (AC), and can be determined by the shape and composition of the oxide semiconductor target. For example, in the case of InGaZnO, it is possible to use a composition ratio such as In:Ga:Zn:O=1:1:1:4 (In₂O₃:Ga₂O₃:ZnO=1:1:2) as the oxide semiconductor target. The composition ratio can be determined in accordance with the purpose such as the characteristics of a transistor.

When the oxide semiconductor film is formed, an oxygen gas, a mixed gas of oxygen and a rare gas, or a rare gas may be used. As a sputtering gas for forming the oxide semiconductor film, in this example, it is preferable to perform the sputtering in a mixed gas atmosphere of oxygen and a rare gas, and it is more preferable that the flow rate ratio of the oxygen gas to the rare gas be 5% or more. By setting the oxygen gas flow rate ratio to 5% or more, oxygen is easily added to the oxide semiconductor film, which is preferable.

A heat treatment may be performed after the oxide semiconductor layer 152 is formed. The heat treatment may be performed at atmospheric or low pressure (vacuum) in the presence of nitrogen, dry air, or air. The heat treatment is preferably performed at 325° C. or higher and 450° C. or less, preferably 350° C. or and higher 400° C. or less. The heating time is desirably performed in, for example, 15 minutes or more and 12 hours or less, preferably 30 minutes or more and 2 hours or less. Oxygen can be filled in a damaged area of the oxide semiconductor layer 152 (a back channel region) or an oxygen vacancy existing in the oxide semiconductor layer 152 by the heat treatment. Thus, the oxygen vacancy included in the oxide semiconductor layer 152 can be reduced, and the oxide semiconductor layer 152 having few crystal defects and high crystallinity can be obtained. The heat treatment can reduce the hydrogen concentration of the oxide semiconductor layer 152. Furthermore, the heat treatment can reduce the defect level density included in the insulating layer 143 and the insulating layer 146. This allows the reliability of the transistor 111 including the oxide semiconductor layer 152 to be improved to have the same reliability as the transistor 110 including the semiconductor layer 142.

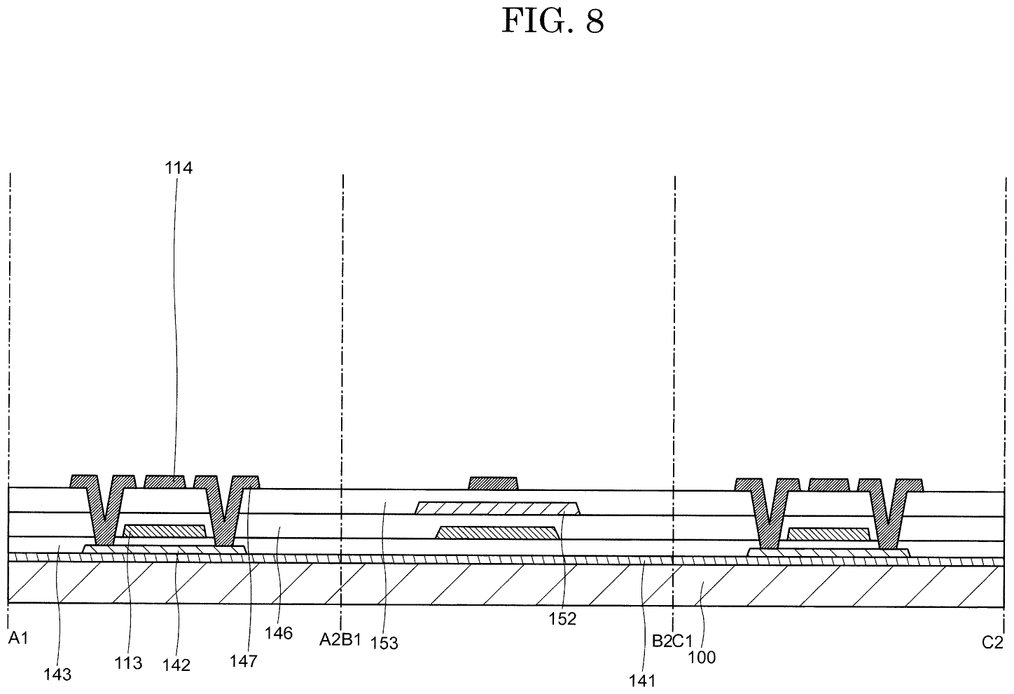

Next, as shown in FIG. 8, the insulating layer 153, the gate line 114 and the source/drain electrodes 147 are formed. The insulating layer 153 is formed by a material, method, and film thickness similar to the insulating layer 146.

After providing an opening in the insulating layer 143, the insulating layer 146, and the insulating layer 153 so as to overlap the semiconductor layer 142 in the source/drain electrodes 147 and the gate line 114, a conductive film to be the source/drain electrodes 147 and the gate line 114 are formed on the semiconductor layer 142 and the insulating layer 153. The conductive film is formed by a sputtering method using any of the above materials. The conductive film is not limited to a sputtering method, and may be formed by a CVD method or a printing method. The film thickness of the source/drain electrodes 147 is preferably 100 nm or more and 1000 nm or less. In this example, titanium, aluminum, and titanium are formed by a sputtering method and processed into desired shapes by a photolithography method and a dry etching method for the source/drain electrodes 147.

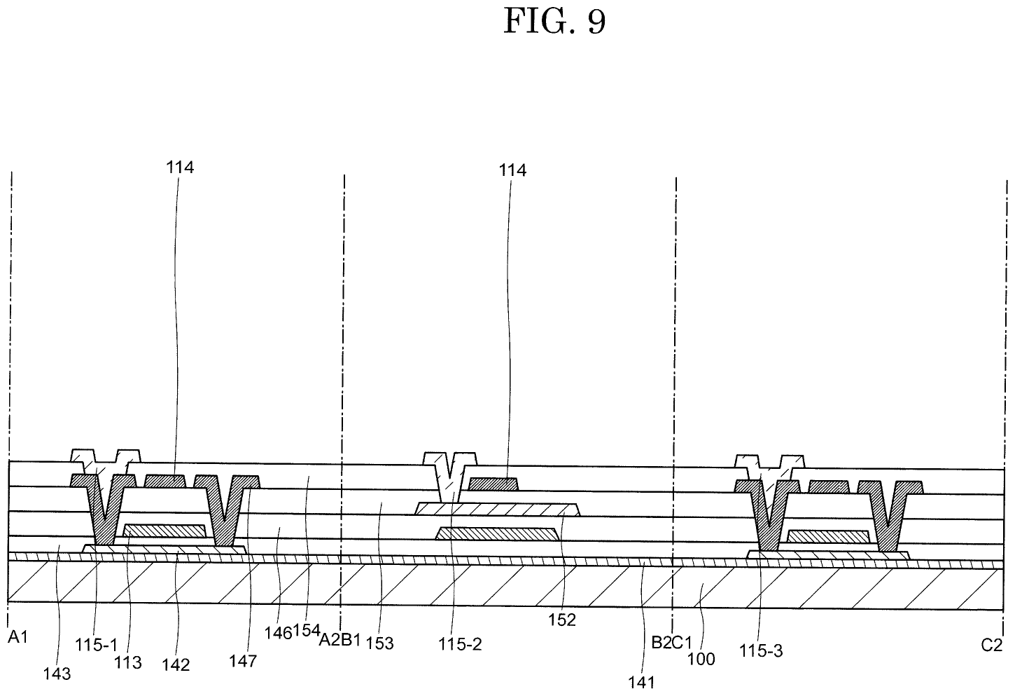

Next, as shown in FIG. 9, the insulating layer 154 and the signal line 115-1, the signal line 115-2, and the signal line 115-3 are formed. The insulating layer 154 is formed using a material, method, and film thickness similar to the insulating layer 143.

The signal line 115-1 is formed on the source/drain electrodes 147 and the insulating layer 154 after an opening is provided in the insulating layer 154 so as to overlap the source/drain electrodes 147. The signal line 115-2 is formed using a material, method, and film thickness similar to the source/drain electrodes 147 and processed into the desired shape by a photolithography method and a dry etching method.

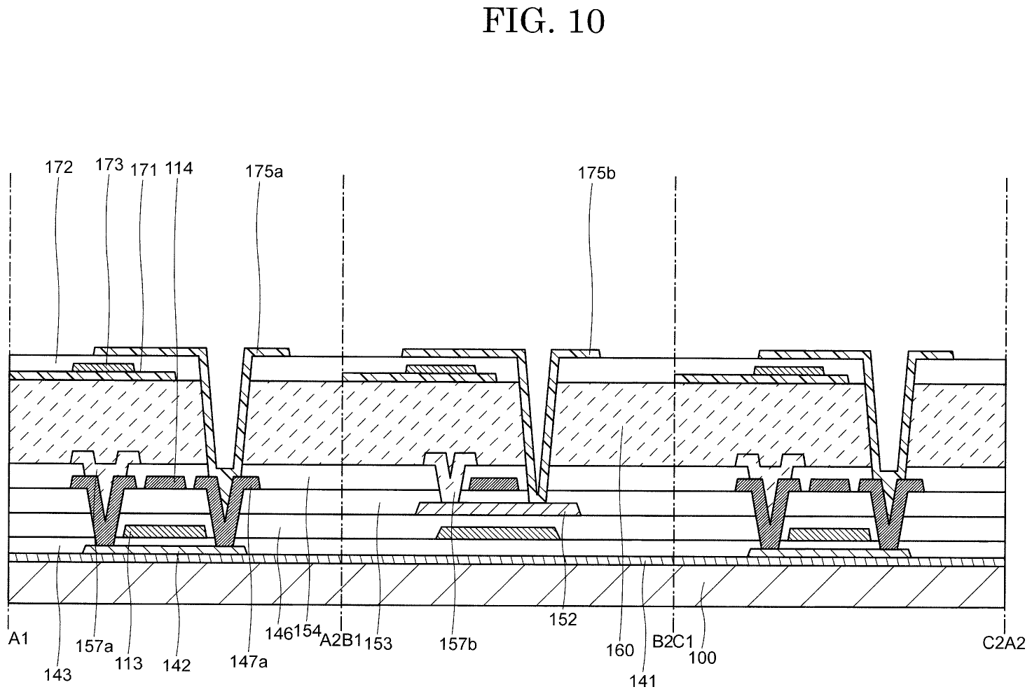

Next, as shown in FIG. 10, the planarization layer 160, the common electrode 171, the conductive layer 173, the insulating layer 172, the pixel electrode 175a, and the pixel electrode 175b are formed. The insulating layer 154 and the insulating layer 172 are formed using a material, method, and film thickness similar to the insulating layer 143.

The planarization layer 160 is formed on the insulating layer 154 and the signal line 115-1 by a coating method or printing method using the materials described above.

The common electrode 171 is formed by a sputtering method using the materials described above, and processed into the desired shape by a photolithography method and a dry etching method. The conductive layer 173 may be appropriately formed on the common electrode 171 to reduce resistance. A material having a low resistance, such as aluminum may be formed on the conductive layer 173 by a sputtering method. The conductive layer 173 is processed and formed by a photolithography method and a dry etching method to overlap the source/drain electrodes 147 and the signal line 115.

The pixel electrode 175a is formed on the source/drain electrodes 147 and the insulating layer 172 after providing an opening in the insulating layer 172, the planarization layer 160, and the insulating layer 154 to overlap the source/drain electrodes 147. The pixel electrode 175b is formed on the oxide semiconductor layer 152 and the insulating layer 172 after providing an opening in the insulating layer 172, the planarization layer 160, the insulating layer 154, and the insulating layer 153 to overlap the oxide semiconductor layer 152. The pixel electrode 175a and the pixel electrode 175b are formed by the same material and method as those of the common electrode 171, and are processed into a desired shape by a photolithography method and a dry etching method.

In addition, since the liquid crystal layer 180, the planarization layer 190, the light-shielding layer 192, and the color filter layer 195 can be formed by a general method, a description thereof will be omitted. The display device 10 can be manufactured by the above method.

In the present embodiment, the temperature applied to the transistors 110 and the transistor 111 at the time of forming the semiconductor layer is different from each other. The semiconductor layer 142 of the transistor 110 requires processing at a higher temperature than the oxide semiconductor layer 152 of the transistor 111. On the other hand, since the oxide semiconductor layer 152 of the transistor 111 is arranged above the semiconductor layer 142, and formed at a temperature lower than the semiconductor layer 142, the transistor 110 is not affected by the heat at the time of forming the transistor 111 (or the influence is small). Therefore, restriction on the process temperature when manufacturing the display device is suppressed. By forming the semiconductor layer of adjacent transistors in different layers, processing constraints are suppressed even when the distance between adjacent transistors (e.g., semiconductor layer) is shortened. For example, when an i-line stepper is applied, the exposure limit is 1.5 μm. However, this configuration is formed in a different layer, and therefore, is not subject to this restriction. As a result, it has the feature that it is easy to process even if a general manufacturing device is used. As described above, by using the present embodiment, it becomes easier to manufacture a high-definition display device.

### Second Embodiment

In the first embodiment, an example in which the transistor 110 includes the semiconductor layer 142 containing a silicon material and the transistor 111 includes the oxide semiconductor layer 152 containing an oxide semiconductor material is described. However, the present invention is not limited to this configuration. In the present embodiment, a display device in which a material used for the semiconductor layer is different from that of the display device of the first embodiment will be described.

### (Configuration of Display 101A)

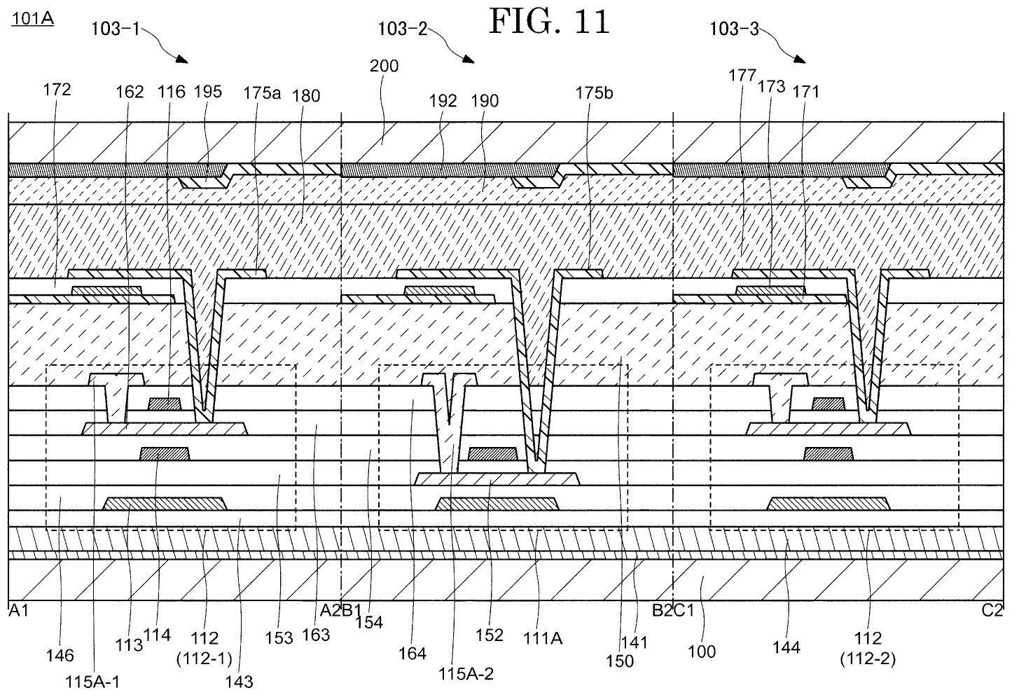

FIG. 11 is a cross-sectional view of a display portion 101A. FIG. 11 is a cross-sectional view similar to FIG. 4. As shown in FIG. 11, the display portion 101 includes transistors 112 (transistor 112-1 and transistor 112-2), an intermediate layer 144, an insulating layer 163, and an insulating layer 164 in addition to the substrate 100, a transistor 111A, the liquid crystal element 170, the light-shielding layer 192, and the substrate 200. The intermediate layer 144 is not limited to a metal material or an insulating material, and may include a wiring substrate or the like.

The transistor 111A has the insulating layer 143, the gate line 113, the insulating layer 146, the oxide semiconductor layer 152, the insulating layer 153, the gate line 114, the insulating layer 154, the insulating layer 163, the insulating layer 164, and a signal line 115A-2.

The transistors 112 have the insulating layer 143, the gate line 113, the insulating layer 146, the insulating layer 153, the gate line 114, the insulating layer 154, an oxide semiconductor layer 162, the insulating layer 163, a gate line 116, the insulating layer 164, and a signal line 115A-1.

The oxide semiconductor layer 162 is provided on the insulating layer 154. The oxide semiconductor layer 162 is formed using a material and a method similar to the oxide semiconductor layer 152.

The insulating layer 163 is provided on the insulating layer 154 and the oxide semiconductor layer 162. The insulating layer 163 is formed using a material and method similar to the insulating layer 143.

The signal line 115A-1 is connected to the oxide semiconductor layer 162 at an opening provided in the oxide semiconductor layer 162, the insulating layer 163, and the insulating layer 164 in the transistors 112. The signal line 115A-2 is connected to the oxide semiconductor layer 152 at an opening provided in the insulating layer 153, the insulating layer 154, the insulating layer 163, and the insulating layer 164 in the transistor 111. Since both the signal line 115A-1 and the signal line 115A-2 are provided on the insulating layer 164, it can be said that they are provided on the same layer. Since the signal line 115A-1 and the signal line 115A-2 are provided on the same layer, it is easy to design a circuit.

With the above configuration, in the transistors 112, the gate line 113 and the gate line 114 are arranged on the lower side of the oxide semiconductor layer 162, and the gate line 116 is provided on the upper side of the oxide semiconductor layer 162. In this case, in the transistors 112, the gate line 114 and the gate line 116 can apply a voltage from an upper side or a lower side with respect to the oxide semiconductor layer 162. However, the gate line 113 does not apply a voltage directly to the oxide semiconductor layer 162. That is, the gate line 114 and the gate line 116 function as the gates for the transistors 112.

On the other hand, in the transistor 111A, the oxide semiconductor layer 152 is provided between the gate line 113 and the gate line 114. In this case, the gate line 113 can apply a gate voltage from the lower side of the oxide semiconductor layer 152, and the gate line 114 can apply a voltage from the upper side of the oxide semiconductor layer 152. That is, the gate line 113 and the gate line 114 function as the gates for the transistors 112.

In the present embodiment, the semiconductor layers of adjacent transistors are arranged in different layers and contain an oxide semiconductor material, respectively. As a result, the processing restriction is suppressed in the case where the distance between the transistors (e.g., semiconductor layer) is close. Therefore, by using the present embodiment, it becomes easier to manufacture a high-definition display device. By using the oxide semiconductor layer for both transistors, light is not shielded at a contact portion with the pixel electrode, and the aperture ratio is improved.

### Third Embodiment

In the first embodiment, an example in which the semiconductor layer 142 and the oxide semiconductor layer 152 are provided apart from each other in a plan view was shown but is not limited to this example. In this embodiment, a display device in which the arrangement of the semiconductor layer is different from that of the first embodiment will be described.

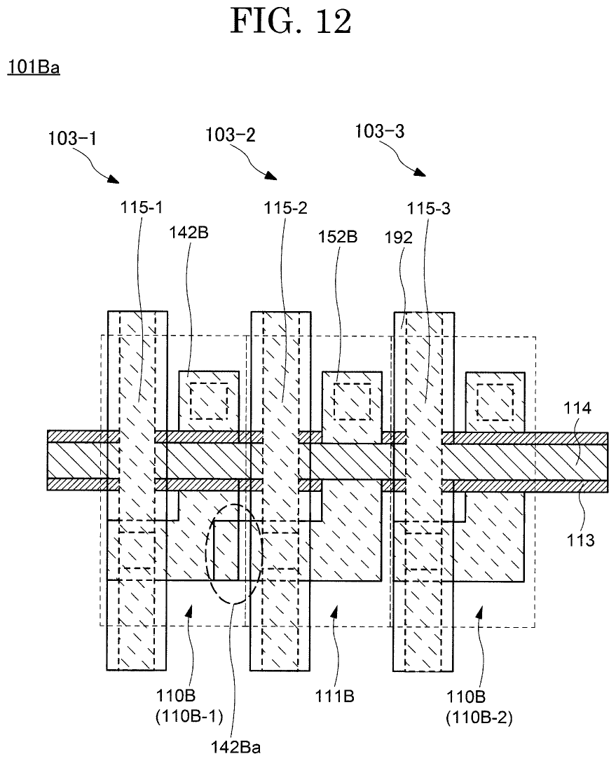

FIG. 12 is a top view of an area 101 Ba of a display portion 101B. The display portion 101B and the area 101 Ba correspond to the display portion 101 and the area 101a of the first embodiment, respectively. As shown in FIG. 12, a semiconductor layer 142B of a transistor 110B-1 and an oxide semiconductor layer 152B of a transistor 111B may be arranged to partially overlap each other (in this example, an area 142Ba). This further increases the degree of freedom in design, and it is easy to provide a high-definition display device.

### EXAMPLE 1

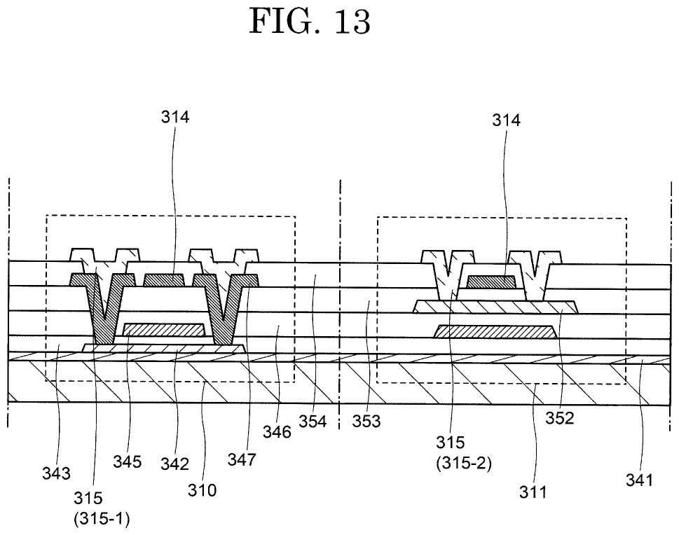

In this example, the transistor 110 and the transistor 111 according to an embodiment of the present invention are manufactured on a substrate, and the results of evaluating Id-Vg characteristics will be described. FIG. 13 is a cross-sectional view of a transistor 310 and a transistor 311 manufactured to evaluate the Id-Vg characteristics. A method of manufacturing the transistor 310 and the transistor 311 is shown below.

First, an insulating layer 341 of silicon oxide was formed on a glass substrate, an amorphous silicon film with a film thickness of 50 nm is formed thereon as a semiconductor layer 342, and a heat treatment is performed at 600° C. to polycrystallize the semiconductor layer 342, and processed using a patterning method and a dry etching method.

Next, a silicon oxide film with a film thickness of 100 nm was formed on the semiconductor layer 342 as an insulating layer 343 by a plasma CVD method at 350° C.

Next, an alloy film (MoW) of molybdenum and tungsten with a film thickness of 200 nm was formed on an insulating layer 346 as a gate electrode 345 corresponding to the gate line 113 by a DC sputtering method, and the film was processed by a patterning method and a dry etching method.

Next, the insulating layer 346 was formed on the gate electrode 345. A stacked film of a silicon nitride film with a film thickness of 150 nm and a silicon oxide film with a film thickness of 100 nm was formed as the insulating layer 346 at 350° C. by a plasma CVD method.

Next, an oxide semiconductor layer 352 was formed on the insulating layer 343 to overlap the gate electrode 345. An IGZO film with a film thickness of 75 nm was formed as the oxide semiconductor layer 352 by an AC sputtering method at 400° C., and the film was processed using a patterning method and a dry etching method.

Next, a stacked film of a silicon oxide film with a film thickness of 200 nm was formed on the insulating layer 346 and the oxide semiconductor layer 352 as an insulating layer 353 by a plasma CVD method at 350° C.

Next, after forming an opening in the insulating layer 353, source/drain electrodes 347 and a gate electrode 314 corresponding to the gate line 114 were formed. Titanium with a film thickness of 50 nm (Ti), aluminum with a film thickness of 200 nm (Al), titanium with a film thickness of 50 nm (Ti) were stacked and formed as the source and drain electrodes 347 and the gate line 114 by a sputtering method, and the film was processed collectively by a patterning method and a dry etching method.

Next, an insulating layer 354 was formed on the source and drain electrodes 347. A silicon oxide film with a film thickness of 300 nm was formed as the insulating layer 354 at 350° C. by a plasma CVD method.

Next, after forming an opening in the insulating layer 354, source/drain electrodes 315 corresponding to the signal line 115 were formed. Titanium with a film thickness of 50 nm (Ti), aluminum with a film thickness of 200 nm (Al), titanium with a film thickness of 50 nm (Ti) were stacked and formed as the source/drain electrodes 315 by a sputtering method, and the film was processed collectively by a patterning method and a dry etching method. The transistor 310 and the transistor 311 were manufactured as described above.

In this example, the Id-Vg characteristics of the manufactured 32 transistors 310 and 84 transistors 311 were evaluated. Measurement of the Id-Vg characteristics of the transistor 310 was performed by applying a voltage (Vg) from −2V to +8V in 0.1V steps to the gate electrode 345 of the transistor 310. The voltage (Vs) applied to the source electrodes of the source/drain electrodes 347 and the source/drain electrodes 315-1 was 0V, and the voltages (Vd) applied to the drain electrodes was 0.1V and 10V. The Id-Vg characteristics of the transistor 310 were measured at room temperature. Measurement of the Id-Vg characteristics of the transistor 311 was performed by applying a voltage (Vg) from −15V to +15V in 0.1V steps to the gate electrode 345 of the transistor 311. The voltage applied to the source electrodes of source/drain electrodes 315-2 (Vs) was 0V, and the voltages applied to the drain electrodes (Vd) were 0.1V and 10V. The Id-Vg characteristics of the transistor 311 were measured at room temperature.

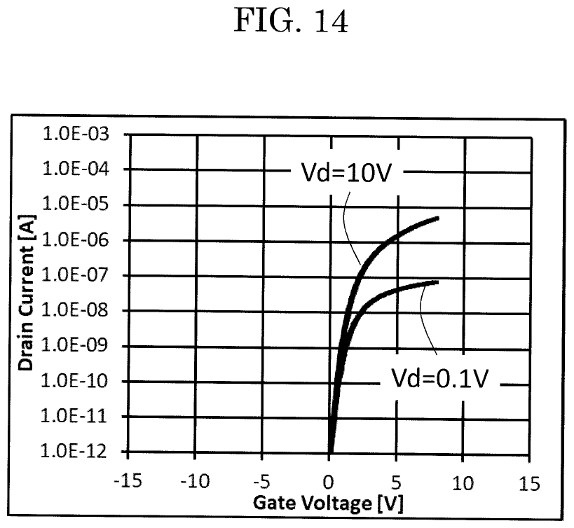

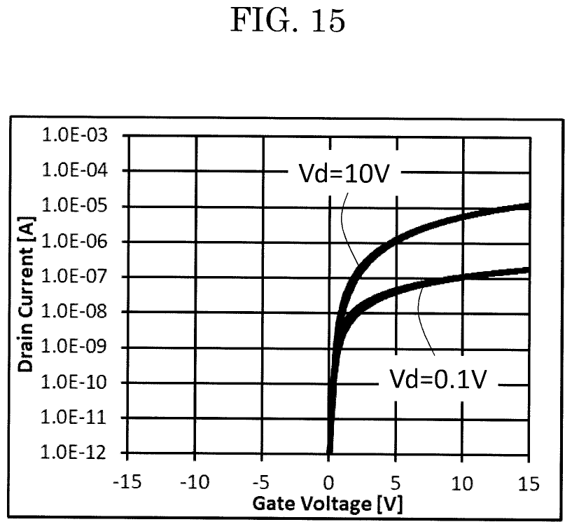

FIG. 14 is the Id-Vg characteristics evaluation result of the 32 transistors 310. FIG. 15 is the Id-Vg characteristics evaluation result of the 84 transistors 311. Table 1 summarizes the threshold voltage (Vth) as the Id-Vg characteristics evaluation result of the 32 transistors 310. Table 2 summarizes the threshold voltages (Vths) as the Id-Vg characteristics evaluation result of the 84 transistors 311. The threshold voltage (Vth) refers to the gate voltage required to pass the drain current in MOSFET.

TABLE 1

| | Vth (V) |
|---|---|
| Average | 0.81 |
| 3σ | 0.37 |
| Max. | 1.08 |
| Min. | 0.51 |

TABLE 2

| | Vth (V) |
|---|---|
| Average | 0.70 |
| 3σ | 0.26 |
| Max. | 0.88 |
| Min. | 0.50 |

As shown in FIG. 14 and Table 1, the mean value (Average), 3σ, the maximum value (Mix), and the minimum value (Min) of the threshold voltage (Vth(V)) of the transistor 310 were 0.81V, 0.37V, 1.08V, and 0.51V, respectively.

As shown in FIG. 15 and Table 2, the mean value (Average), 3σ, the maximum value (Mix), and the minimum value (Min) of the threshold voltage (Vth(V)) of the transistor 311 were 0.70V, 0.26V, 0.88V, and 0.50V, respectively.

Therefore, it was found that the characteristics of the transistor 310 and the transistor 311 of this example show almost the same numerical values, the characteristic variations are small, and the characteristics were stable.

As described above, by using a combination of the transistors according to an embodiment of the present invention, a high-definition display device can be provided.

Within the spirit of the present invention, it is understood that various changes and modifications can be made by those skilled in the art and that these changes and modifications also fall within the scope of the present invention. For example, as long as the gist of the present invention is provided, deletions, or changes to the design of components or additions, omissions, or changes to the conditions of processes to each of the above-described embodiments by a person skilled in the art are included in the scope of the present invention.

What is claimed is:

1. A display device comprising:
a display portion;
a first transistor arranged in the display portion and including a first semiconductor layer;
a second transistor arranged adjacent to the first transistor in the display portion and including a second semiconductor layer arranged in a different layer from the first semiconductor layer;
a first signal line connected to the first transistor;
a second signal line connected to the second transistor,
a gate line overlapping the first transistor and the second transistor; and
a display element arranged on the first transistor and the second transistor.

2. The display device according to claim 1, wherein
the first signal line and the second signal line are arranged on the same surface.

3. The display device according to claim 2, wherein
the first semiconductor layer and the second semiconductor layer partially overlap each other.

4. The display device according to claim 1, wherein
the gate line includes a first gate line and a second gate line, the second gate line overlapping the first gate line and being arranged on a different layer from the first gate line,
the first semiconductor layer of the first transistor is between the first gate line and the second gate line, and
one of the first gate line and the second gate line is between the second semiconductor layer of the second transistor and the other of the first gate line and the second gate line.

5. The display device according to claim 1, further comprising:
a drive circuit arranged in a peripheral portion surrounding the display portion, wherein
the drive circuit includes a third transistor, and
a third semiconductor layer of the third transistor is arranged on the same layer as the first semiconductor layer of the first transistor.

6. The display device according to claim 1, wherein
a material of the first semiconductor layer is different from a material of the second semiconductor layer.

7. The display device according to claim 6, wherein
the first semiconductor layer includes an oxide semiconductor material, and
the second semiconductor layer includes silicon.

8. The display device according to claim 1, wherein
the first semiconductor layer and the second semiconductor layer include an oxide semiconductor material.

9. The display device according to claim 8, wherein
the display element is a liquid crystal element.
